(19) United States
(12) Patent Application Publication
(10) Pub. No.: US 2023/0261087 A1
(43) Pub. Date: Aug. 17, 2023

(54) LOW RANDOM TELEGRAPH NOISE DEVICE

(71) Applicant: Taiwan Semiconductor Manufacturing Company, Ltd., Hsinchu (TW)

(72) Inventors: Chih-Yu Tseng, Hsinchu (TW); Chung-Wen Weng, Hsinchu (TW)

(21) Appl. No.: 17/671,813

(22) Filed: Feb. 15, 2022

(51) Int. Cl. H01L 29/66; H01L 29/786; H01L 29/08

(52) U.S. Cl. CPC H01L 29/665; H01L 29/78696; H01L 29/7869; H01L 29/0847

(57) ABSTRACT

A semiconductor device includes an active area with a source and a drain, a gate oxide disposed on a portion of the active area between the source and the drain, and a gate is disposed over the gate oxide. In a noise suppressing structure, edge oxide regions are disposed on the gate oxide with edges of the edge oxide regions coinciding with the active area edges, and the gate is disposed over the edge oxide regions. In another noise suppressing structure, first and second active area edge extensions of respective first and second active area edges increase a width in the transverse direction of the active area at the edge extensions to a width greater than a minimum width of the active area in the transverse direction. The gate does not completely cover the first and second active area edge extensions along the channel direction.

### BACKGROUND

The following relates to transistor arts, integrated circuit (IC) arts, radio frequency (RF) device arts, to fabrication processes for the foregoing, and to related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 diagrammatically illustrate a perspective view (FIG. 1) and a side sectional view (FIG. 2) of a semiconductor device according to a first embodiment.

FIG. 3 parts (A), (B), and (C) diagrammatically illustrate side sectional views of variant embodiments of the semiconductor device of FIGS. 1 and 2.

FIG. 4 diagrammatically illustrates by way of a flowchart a suitable method of making and using a semiconductor device of the first embodiment.

FIGS. 5 and 6 diagrammatically illustrate a perspective view (FIG. 5) and a top view (FIG. 6) of a semiconductor device according to a second embodiment.

FIG. 7 parts (A), (B), (C), (D), and (E) diagrammatically illustrate top views of variant embodiments of the semiconductor device of FIGS. 5 and 6.

FIG. 8 diagrammatically illustrates by way of a flowchart a suitable method of making and using a semiconductor device of the second embodiment.

FIG. 9 diagrammatically illustrates by way of a flowchart a suitable method of making and using a semiconductor device which combines the first embodiment and the second embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Random telegraph noise (RTN) signals, also referred to as burse noise, popcorn noise, impulse noise, bi-stable noise, random telegraph signal (RTS), or similar nomenclatures, is a type of electronic noise that occurs in some semiconductor devices with thin gate oxide films. It typically manifests as abrupt transitions in operating voltage and/or electric current level. RTN is an important characteristic parameter for high performance radio frequency (RF) and analogue electronics applications. Disclosed herein are methods and corresponding semiconductor devices which reduce RTN.

In some embodiments disclosed herein, reduction in RTN is advantageously achieved without any additional processing steps, but rather by modifying the geometry of the device active area. Consequently, these embodiments advantageously reduce RTN without introducing additional processing time or cost.

In some embodiments disclosed herein, reduction in RTN is advantageously achieved with only minor additional processing, such as adding an additional mask and oxide formation step to form an additional edge oxide regions at the edges of the channel. Consequently, these embodiments advantageously reduce RTN with limited additional processing time or cost.

In some embodiments disclosed herein, reduction in RTN is advantageously achieved without reducing the channel width of the transistor or other semiconductor device.

In some embodiments disclosed herein, reduction in RTN is advantageously achieved without modifying the channel of the transistor or other semiconductor device.

Transistors or other semiconductor devices with reduced RTN as disclosed herein are expected to find advantageous application in substantially any type of narrowband or wideband RF integrated circuit (IC), and in any type of IC that generates or processes signals in a narrowband or wideband RF range. Such ICs include, by way of nonlimiting illustrative example, microprocessors, microprocessors or other types of electronic processing ICs, memory ICs or other types of ICs that incorporate field effect transistors (FETs), memory cell arrays, image sensor chips, and/or so forth.

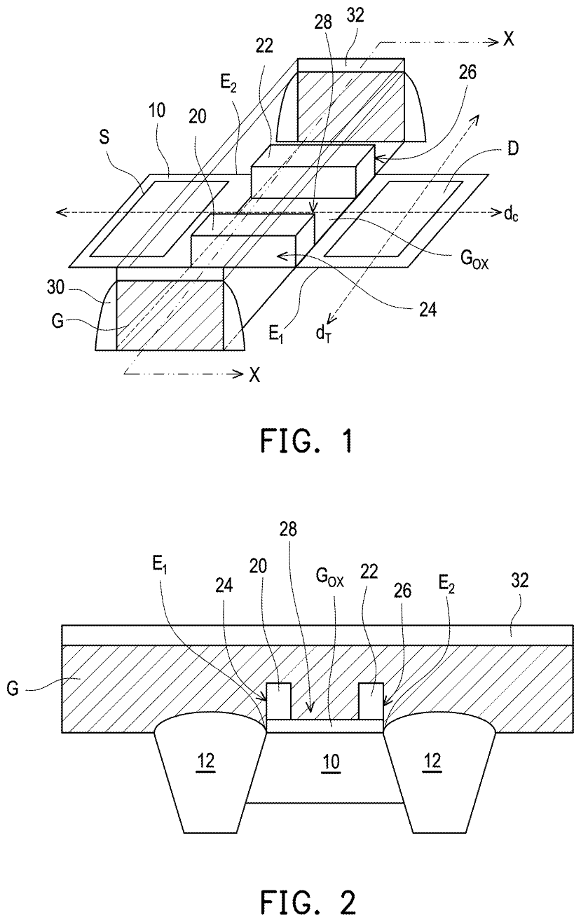

With reference to FIGS. 1 and 2, a semiconductor device according to a first embodiment is diagrammatically illustrated by a perspective view (FIG. 1) and a side sectional view (FIG. 2) taken along the vertical Section X-X indicated in FIG. 1. The semiconductor device includes an active area 10 bounded by an isolation region 12, such as shallow trench isolation (STI), a local oxidation of silicon (LOCOS) region, or so forth. The active area 10 includes a source S and a drain D in the active area 10. The active area 10 has a channel direction d_{C} that extends between the source S and the drain D, and a transverse direction d_{T} that is transverse to the channel direction d_{C}. The active area 10 has first and second active area edges E₁ and E₂ on opposite sides of the active area 10 that extend along the channel direction d_{C} between the source and the drain.

The active area 10 including the source S and drain D and bounded by the isolation region 12 in some embodiments, corresponds to the source, drain, and channel regions of a field effect transistor (FET), such as a p-type metal-oxide-semiconductor FET (p-MOSFET) or an n-type MOSFET, a lateral double-diffusion MOSFET (LDMOS), or so forth. The active area 10 may in general be one illustrative electronic component of an integrated circuit (IC) which may include dozens, hundreds, thousands, or more such semiconductor devices. To this end the active area 10 may include p-type and/or n-type doping wells (e.g., p-well and/or n-well regions) formed in portions of the active region 10 in accordance with the chosen semiconductor device. These doped regions may be formed by ion implantation, dopant diffusion, or so forth. The starting substrate may, by way of nonlimiting illustration, be a silicon substrate (doped n-type or p-type depending on the chosen semiconductor device), a silicon-on-insulator (SOI) wafer, or so forth. The various processes for forming the active area 10 and surrounding isolation 12 are typically controlled photolithographically using one or more photolithography masks, such as an oxide diffusion (OD) mask for defining the active area 10.

A gate oxide Gₒₓ is disposed on a portion of the active area 10 between the source S and the drain D. The gate oxide Gₒₓ may be formed by any suitable technique, such as chemical vapor deposition (CVD), physical vapor deposition (PVD), atomic layer deposition (ALD), thermal oxidation, or so forth. The gate oxide Gₒₓ may be silicon dioxide or silicon oxide of another stoichiometry, or may be a high dielectric constant (high- K) dielectric material such as silicon oxynitride or so forth. The illustrative semiconductor device of FIGS. 1 and 2 may be a radio frequency (RF) or analog device that in use is switched over narrow- and/or wideband RF frequencies. For improved RF operation, the gate oxide Gₒₓ is suitably thin, for example having a thickness of 15.0 nm or less in some embodiments, and a thickness of 4.0 nanometers or less in some more restrictive embodiments.

Conventionally, use of a thin gate oxide in a semiconductor device can lead to random telegraph noise (RTN) during operation of the device. Without being limited to any particular theory of operation, RTN is believed to be due to random trapping and release of carriers (electrons or holes, depending on the nature of the semiconductor device) conducting across the channel between the source S and drain D. RTN is an important characteristic parameter for high performance RF and analog electronics applications.

With continuing reference to FIGS. 1 and 2, to suppress RTN the semiconductor device of FIGS. 1 and 2 further includes a first edge oxide region 20 and a second edge oxide region 22 disposed on edges of the gate oxide Gₒₓ. The first edge oxide region 20 is disposed on the gate oxide Gₒₓ with an edge 24 of the first edge oxide region 20 coinciding with the first active area edge E1. Likewise, a second edge oxide region 22 is disposed on the gate oxide Gₒₓ with an edge 26 of the second edge oxide region 22 coinciding with the second active area edge E2. The first and second edge oxide regions 20, 22 do not extend over a central area 28 of the gate oxide Gₒₓ. As will be further discussed herein, the edge oxide regions 20 and 22 suppress RTN. The edge oxide regions 20 and 22 are suitably formed by CVD, PVD, ALD, or another suitable deposition method. To restrict deposition of the edge oxide regions 20 and 22 to the edges of the gate oxide Gₒₓ, a different photolithography mask (e.g., a second photolithography mask) is used for controlling formation of the edge oxide regions 20 and 22 compared with the (first) photolithography mask used to control formation of the gate oxide Gₒₓ.

A gate G is disposed over the gate oxide Gₒₓ and over the first and second edge oxide regions 20 and 22. The gate G may, for example, comprise polysilicon or another suitably electrically conductive material. Depending on the fabrication process, optional spacers 30 may be formed on the sides of the gate G. To facilitate electrical contact to the gate G, a self-aligned silicide (salicide) layer 32 is optionally formed on top of the gate G. The silicide may, for example, be titanium silicide, cobalt silicide, nickel silicide, platinum silicide, erbium silicide, palladium silicide, or so forth. The self-aligned formation process can entail depositing the metal material (e.g., titanium, cobalt, et cetera, or an alloy thereof) by sputtering or another suitable deposition technique at a temperature of around 500-900° C. to form the silicide by reaction of the metal with the underlying silicon, followed by etching removal of the unreacted metal.

As previously noted, the first and second edge oxide regions 20 and 22 disposed on the opposite edges of the gate oxide Gₒₓ provide suppression of RTN. Without being limited to any particular theory of operation, it is believed that RTN suppression is provided because the edge oxide regions 20 and 22 generate areas of higher voltage at the peripheral edges of the channel underlying the edge oxide regions 20 and 22, compared with the portion of the channel underneath the central region 28 of the gate oxide Gₒₓ. This higher voltage biases the carrier flow through the channel away from the edges E₁ and E₂ of the active area 10 and toward the central region 28 of the gate oxide Gₒₓ. This effect can be seen by considering the gate oxide as a capacitor in which charge Q˜CΔV, where C is the capacitance (per unit area) and ΔV is the applied voltage. Modeling the (per unit area) capacitance of the gate oxide as

$$C = ε ( \frac{A}{d} )$$

where A is the area, d is the gate oxide thickness, and ε is the dielectric constant, it follows that the edge oxide regions 20 and 22 increase the thickness d of the gate oxide proximate to the edges E₁ and E₂ of the active area 10 and thus correspond to lower per-unit area capacitance C. Hence, for a given applied voltage ΔV, the distribution of the charge Q˜CΔV is shifted away from the edge regions. That is, less charge is expected to accumulate in the edge regions underneath the edge oxide regions 20 and 22 compared with underneath the central region 28 of the gate oxide Gₒₓ.

The edges E₁ and E₂ of the active area 10 are expected to have a relatively high concentration of point defects forming carrier traps. The point defects can arise, for example, due to damage to the silicon material during formation of the isolation region 12 surrounding the active area 10. For example, if the isolation region 12 comprises shallow trench isolation (STI), then the formation of the STI region 12 entails etching trenches in the silicon and depositing silicon dioxide or another electrical insulator in the trenches. These processes can produce damage to the adjacent silicon at the edges E₁ and E₂ of the active area 10, thereby introducing point defects that can act as carrier traps. As RTN is believed to be due to random trapping and release of charge carriers underneath the thin gate oxide Gₒₓ, biasing of the carrier flow away from the edges E₁ and E₂ of the active area 10 by way of the edge oxide regions 20 and 22 is expected to reduce RTN of the semiconductor device of FIGS. 1 and 2. Optimization of the lateral extent of the edge oxide regions 20 and 22 as well as the thickness of the edge oxide regions 20 and 22 can be readily optimized empirically by fabricating devices with different edge oxide thicknesses and lateral extents and measuring the RTN, or optimal values can be estimated by electrostatic modeling of the device structure with suitable estimates of trap densities at the edges of the active area.

Notably, in some embodiments the formation of the semiconductor device does not include forming ion implantation regions in the active area 10 underneath the first and second edge oxide regions 20 and 22. Consequently, the channel extends underneath the first and second edge oxide regions 20 and 22, providing a channel width that is not reduced by the inclusion of the edge oxide regions 20 and 22.

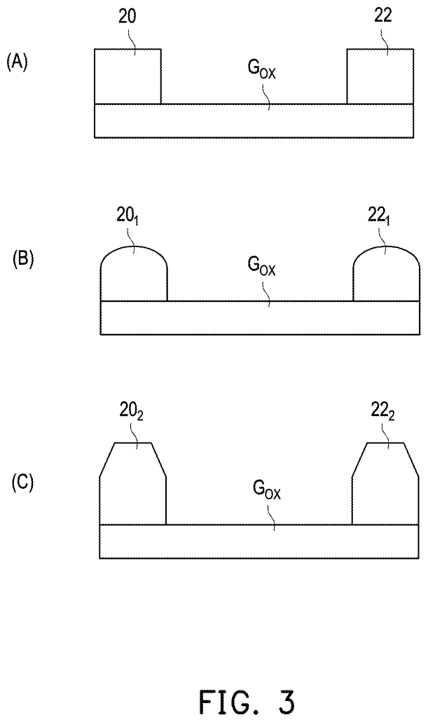

With reference to FIG. 3, parts (A), (B), and (C), some further examples of some suitable cross-sectional geometries for the edge oxide regions 20 and 22 are illustrated. For simplicity, FIG. 3 parts (A), (B), and (C) depict only the gate oxide Gₒₓ and the edge oxide regions. FIG. 3 part (A) depicts the edge oxide regions 20 and 22 of FIGS. 1 and 2, in which the edge oxide regions 20 and 22 have rectangular cross-sections. This design is often straightforward from a fabrication vantage. FIG. 3 part (B) depicts a variant embodiment in which edge oxide regions 20₁ and 22₁ are dome-shaped, or have dome-shaped upper regions. This design can also be straightforward from a fabrication vantage if the deposition process forming the edge oxide regions 20₁ and 22₁ produces a rounded upper surface of the edge oxide regions 20₁ and 22₁. FIG. 3 part (C) depicts another variant, in which edge oxide regions 20₂ and 22₂ have faceted tops so that the overall cross-section is pentagonal in shape. These are merely illustrative examples, and other cross-sectional geometries for the edge oxide regions are contemplated.

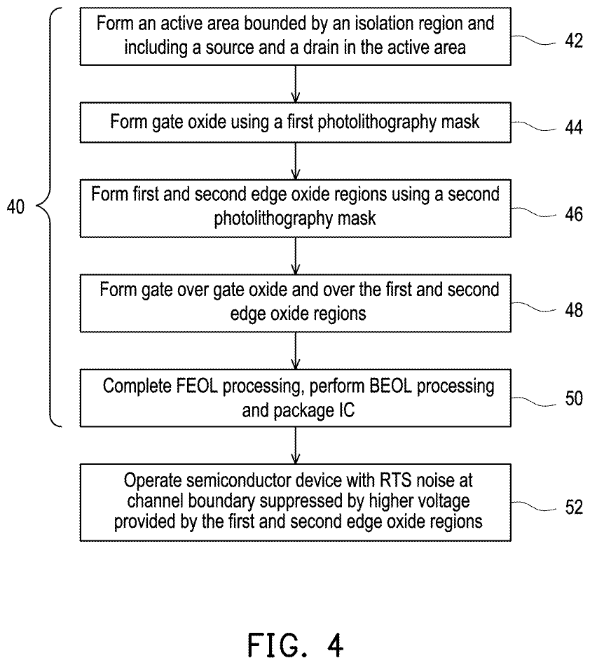

With reference to FIG. 4, a method of making and using a semiconductor device such as that of FIGS. 1 and 2 is illustrated by way of a flowchart. The fabrication process entails the blocks indicated generally as fabrication process 40, and begins with an operation 42 in which the active region 10 bounded by the STI or other isolation 12 is formed, including forming the source S and drain D in the active area. The operation 42 can employ any sequence of fabrication (sub-)steps suitable for fabricating the chosen device design (e.g., p-MOSFET, n-MOSFET, LDMOS, et cetera). For example, the operation 42 may include initial formation of the STI region 12 by way of trench etching followed by depositing silicon dioxide or other insulation material in the trenched, and formation of n-well and/or p-well regions defining the active area 10 and the source S and drain D regions by dopant diffusion, ion implantation, epitaxial deposition, various combinations thereof, and/or so forth, with the modified areas being controlled using suitable photolithographic techniques employing an OD photolithography mask and optionally additional masks. The operation 42 suitably forms the active area 10 and isolation 12 on and/or in a silicon substrate (doped n-type or p-type depending on the chosen semiconductor device), SOI substrate, or so forth. The silicon, SOI, or other substrate may optionally include an epitaxial layer or layer stack on or in which the operation 42 forms the active area 10 and isolation 12.

In an operation 44, the gate oxide Gₒₓ is formed, with the area of the gate oxide being defined using a first photolithography mask. In an operation 46, the first and second edge oxide regions 20 and 22, with the areas of the edge oxide regions 20 and 22 being defined using a second photolithography mask that is different from the first photolithography mask. The operations 44 and 46 can employ any suitable insulator formation or deposition technique, such as CVD, PVD, ALD, thermal oxidation, various combinations thereof, or so forth, and the formed gate oxide Gₒₓ and edge oxide regions 20 and 22 can comprise silicon dioxide or silicon oxide of another stoichiometry, a high-K dielectric such as silicon nitride (Si₃N₄) or more generally a silicon oxynitride, hafnium dioxide, or so forth. Since the edge oxide regions 20 and 22 are deposited in a separate step 46 from the formation 44 of the gate oxide Gₒₓ, it is contemplated for the edge oxide regions 20 and 22 to comprise a different insulator material than the gate oxide Gₒₓ.

To implement the variant embodiments of FIGS. 3(B) and 3(C), the operation 46 may optionally include an additional mask to define the shaped tops of the edge oxide extensions 20₁, 22₁ of FIG. 3(B) or the shaped tops of the edge oxide extensions 20₂, 22₂ of FIG. 3(C). Alternatively, the deposition method used to form the edge oxide extensions may naturally form these domed or narrowing tops, for example if the deposition rate is faster in the central area of the photoresist openings defining the areas of the edge oxide extensions compared with in the periphery of the photoresist openings.

In an operation 48, the gate G is formed over the gate oxide Gₒₓ and over the edge oxide regions 20 and 22. The gate G may comprise polysilicon or another suitably electrically conductive material, and the operation 48 may optionally further include formation of the spacers 30 to (further) isolate the gate G, and/or may optionally further include formation of the salicide layer 32 to improve electrical contact to the gate G. As seen in FIGS. 1 and 2, the area of the gate G may extend in the transverse direction d_{T} beyond the area of the gate oxide Gₒₓ and overlying edge oxide regions 20 and 22. In the illustrative embodiments, the gate G completely covers the first and second edge oxide regions 20 and 22.

The fabrication operations 42, 44, 46, and 48 are typically considered part of the front end-of-line (FEOL) processing for fabrication of an IC. In an operation 50, the FEOL is completed (if it is not already complete at the end of operation 48) and back end-of-line (BEOL) processing is performed, followed by packaging of the IC. The BEOL processing typically includes photolithographically patterned deposition of one or more metallization layers with interconnecting vias to electrically interconnect electronic components of the IC, while packaging may include operations such as dicing the wafer (e.g., silicon or SOI substrate) on which the IC is fabricated into individual IC dies, and optionally mounting the IC dies in packages including electrically connecting leads of the package with contact pads of the IC formed during the BEOL processing. Although not shown, some more complex IC fabrication workflows may include a middle end-of-line (MEOL) process that includes a mixture of FEOL-type and BEOL-type fabrication process operations.

At some point after the fabrication process 40 is completed, the fabricated IC is deployed in an electronic device or system, and the IC is operated, including an operation 52 in which the semiconductor device fabricated by the fabrication process 40 is operated. In the device operation 52, RTN is suppressed by the higher voltage at the edges of the channel compared with in the central region 28 of the channel, where the higher voltage is a consequence of the edge oxide regions 20 and 22. Viewed another way, the RTN is suppressed by the higher thickness d of the gate oxide proximate to the edges E₁ and E₂ of the active area 10 due to the edge oxide regions 20 and 22 providing a lower per-unit area capacitance C at the edges, thus shifting electrical charge away from the edge regions and toward the central region 28 of the channel. This reduces the extent of charge trapping near the edges E₁ and E₂ of the active area, and hence reduces the RTN characteristic of the device.

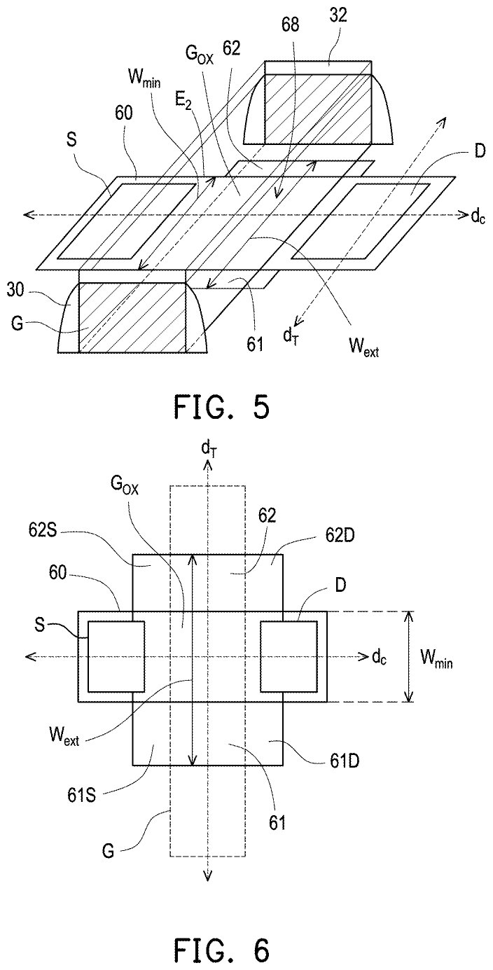

With reference now to FIGS. 5 and 6, a perspective view (FIG. 5) and a top view (FIG. 6) of a semiconductor device according to a second embodiment is diagrammatically illustrated. The semiconductor device of FIGS. 5 and 6 has similarities to the semiconductor device of FIGS. 1 and 2, including having an active area 60 analogous to the active area 10 of the embodiment of FIGS. 1 and 2, which is bounded by an isolation region (not shown in FIGS. 1 and 2). As in the embodiment of FIGS. 1 and 2, the active area 60 includes a source S and a drain D in the active area 60, and has a channel direction dc that extends between the source S and the drain D, and a transverse direction d_{T} that is transverse to the channel direction d_{C}. The semiconductor device of FIGS. 5 and 6 further includes the gate G with optional spacers 30 and optional silicide 32.

The illustrative semiconductor device of FIGS. 5 and 6 does not include the edge oxide regions 20 and 22 of the embodiment of FIGS. 1 and 2, although these could optionally also be included in the embodiment of FIGS. 5 and 6.

The active area 60 of the embodiment of FIGS. 5 and 6 has first and second active area edges on opposite sides of the active area 60 that extend along the channel direction d_{C} between the source and the drain. However, unlike the active area 10 of the embodiment of FIGS. 1 and 2, in the embodiment of FIGS. 5 and 6 the first and second active area edges have respective first and second active area edge extensions 61 and 62 that increase a width in the transverse direction d_{T} of the active area 60 at the edge extensions 61, 62 to a width Wₑₓₜ that is greater than a minimum width Wₘᵢₙ in the transverse direction d_{T} of the active area 60.

The first and second active area edge extensions 61 and 62 provide suppression of RTN. Without being limited to any particular theory of operation, it is believed that RTN suppression is provided because the first and second active area edge extensions 61 and 62 provide electric current path extensions for the channel current flowing through the channel between the source S and the drain D. The current density through the channel is expected to be largest in a central area 68 of the channel, with the electric current density gradually decreasing in the active area edge extensions 61 and 62 with increasing distance in the transverse direction d_{T} from the center of the channel. As previously discussed, the edges of the active area 60 are expected to have a relatively high concentration of point defects forming carrier traps. As RTN is believed to be due to random trapping and release of charge carriers underneath the thin gate oxide Gₒₓ, the reduced electric current in the active area edge extensions 61 and 62 reduces the fraction of the channel current that is exposed to the higher density of carrier traps at the channel edges, and thus reduces the RTN characteristic of the semiconductor device of FIGS. 5 and 6. The lateral extent of the active area edge extensions 61 and 62 can be readily optimized empirically by fabricating devices with different edge extension sizes and measuring the RTN, or optimal values can be estimated by device electrical current flow modeling of the device structure with suitable estimates of trap densities at the edges of the active area.

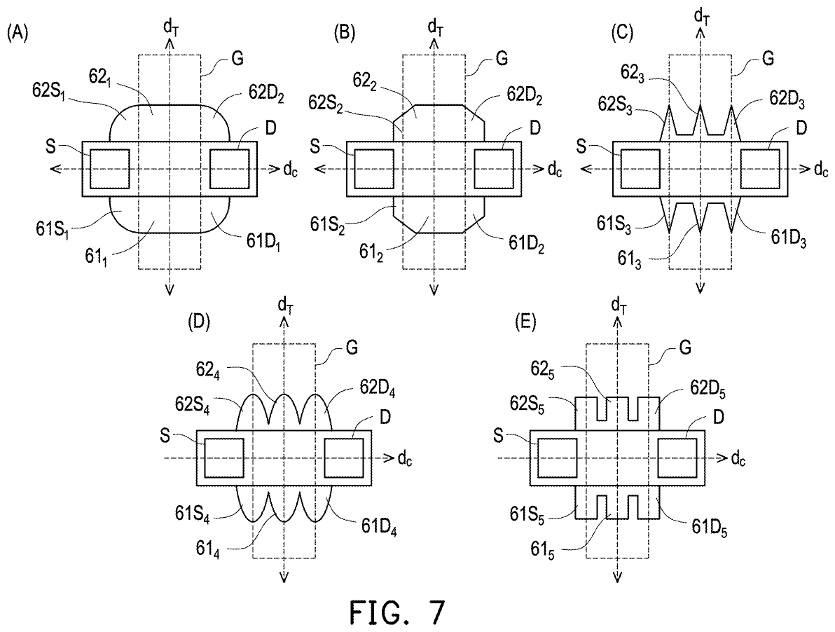

In the illustrative embodiment of FIGS. 6 and 7, the gate G does not completely cover the first and second active area edge extensions 61 and 62 along the channel direction d_{C}. More particularly (and as labeled in the top view of FIG. 6): the first active area edge extension 61 includes an edge extension portion 61S that extends beyond the gate G toward the source S along the channel direction d_{C}; the second active area edge extension 62 includes an edge extension portion 62S that extends beyond the gate G toward the source S along the channel direction d_{C}; the first active area edge extension 61 includes an edge extension portion 61D that extends beyond the gate G toward the drain D along the channel direction d_{C}; and the second active area edge extension 62 includes an edge extension portion 62D that extends beyond the gate G toward the drain D along the channel direction d_{C}. These edge extension portions 61S, 62S, 61D, and 62D provide for a smooth channel current flow in the vicinity of the active area edge extensions 61 and 62, and avoids having the channel electric current encounter high trap densities at abrupt corners of the active area 60 underneath the gate G.

With reference to FIG. 7 parts (A), (B), (C), (D), and (E), the geometry of the active area edge extensions can vary, and some variant embodiments of the active area edge extensions 61 and 62 are shown by top view in FIG. 7. Starting with FIG. 6, that embodiment shows active area edge extensions 61 and 62 having rectangular shapes. The embodiment of FIG. 7 part (A) has first and second active area edge extensions 61₁ and 62₁ with edge extension portions 61S₁, 61D₁, 62S₁, and 62D₁ not covered by the gate G that have rounded or arcuate perimeters, rather than the rectangular edge extension portions 61S, 61D, 62S, and 62D extending beyond the gate G in the embodiment of FIG. 6.

The embodiment of FIG. 7 part (B) shows an embodiment having first and second active area edge extensions 61₂ and 62₂ that are polygonal (but not rectangular) in shape, with edge extension portions 61S₂, 61D₂, 62S₂, and 62D₂ not covered by the gate G that are polygonal but not rectangular.

The embodiment of FIG. 7 part (C) shows an embodiment having sawtooth shaped first and second active area edge extensions 61₃ and 62₃, with edge extension portions 61S₃, 61D₃, 62S₃, and 62D₃ not covered by the gate G that comprise portions of the outermost teeth of the sawtooth pattern.

The embodiment of FIG. 7 part (D) shows an embodiment having circle-tooth shaped first and second active area edge extensions 61₄ and 62₄, with edge extension portions 61S₄, 61D₄, 62S₄, and 62D₄ not covered by the gate G that comprise portions of the outermost circle-tooths of the circle-tooth shaped pattern.

The embodiment of FIG. 7 part (E) shows an embodiment having square-tooth shaped first and second active area edge extensions 61₅ and 62₅, with edge extension portions 61S₅, 61D₅, 62S₅, and 62D₅ not covered by the gate G that comprise portions of the outermost square-tooths of the square-tooth shaped pattern.

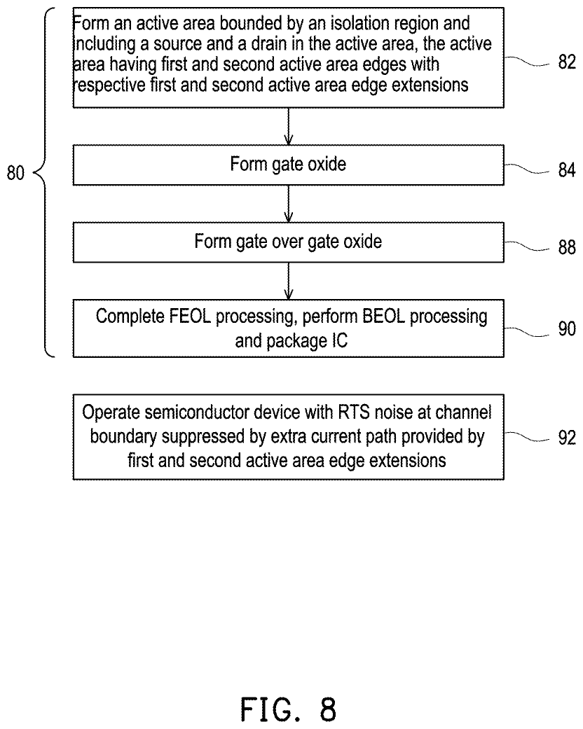

With reference to FIG. 8, a method of making and using a semiconductor device such as that of FIGS. 5 and 6 is illustrated by way of a flowchart. The fabrication process entails the blocks indicated generally as fabrication process 80, and begins with an operation 82 in which the active region 60 bounded by the STI or other isolation 12 is formed, including forming the source S and drain D in the active area. The operation 82 is analogous to the operation 42 of FIG. 4, and can employ any sequence of fabrication (sub-)steps suitable for fabricating the chosen device design (e.g., p-MOSFET, n-MOSFET, LDMOS, et cetera). In the operation 82, however, the OD photolithography mask used to define the active area 60 suitably includes the first and second active area edge extensions 61 and 62 (or includes the active area edge extensions 61₁, 62₁ or the active area edge extensions 61₂, 62₂ or the active area edge extensions 61₃, 62₃ or the active area edge extensions 61₄, 62₄ or the active area edge extensions 61₅, 62₅ of respective variant embodiments FIG. 7(A)-7(E)).

With continuing reference to FIG. 8, in an operation 84 corresponding to the operation 44 of FIG. 4, the gate oxide Gₒₓ is formed, again with the area of the gate oxide being defined using a suitable photolithography mask. In an operation 88 corresponding to the operation 48 of FIG. 4, the gate G is formed over the gate oxide Gₒₓ. (This differs from the fabrication flow of FIG. 4 in that the operation 46 is omitted, so that the operation 88 forms the gate G over the gate oxide Gₒₓ but not over the omitted edge oxide regions 20 and 22). The gate G again may comprise polysilicon or another suitably electrically conductive material, and the operation 48 may optionally further include formation of the spacers 30 to (further) isolate the gate G, and/or may optionally further include formation of the salicide layer 32 to improve electrical contact to the gate G. Also again, the area of the gate G may extend in the transverse direction d_{T} beyond the area of the gate oxide Gₒₓ, for example as seen in FIG. 6 and FIGS. 7(A)-(E). In the illustrative embodiments, the gate G completely covers the first and second edge oxide regions 20 and 22.

The fabrication operations 82, 84, and 88 are typically considered part of the FEOL processing. In an operation 90 analogous to the operation 50 of FIG. 4, the FEOL is completed (if it is not already complete at the end of operation 88) and BEOL processing is performed, followed by packaging of the IC. Although not shown, some more complex IC fabrication workflows may include a MEOL process as well. At some point after the fabrication process 80 is completed, the fabricated IC is deployed in an electronic device or system, and the IC is operated, including an operation 92 in which the semiconductor device fabricated by the fabrication process 80 is operated. In the device operation 92, RTN is suppressed by the gradually decreasing current density in the active area edge extensions 61 and 62 (or analogous active area edge extensions of the embodiments of FIGS. 7(A)-7(E)) with increasing distance in the transverse direction d_{T} from the center of the channel.

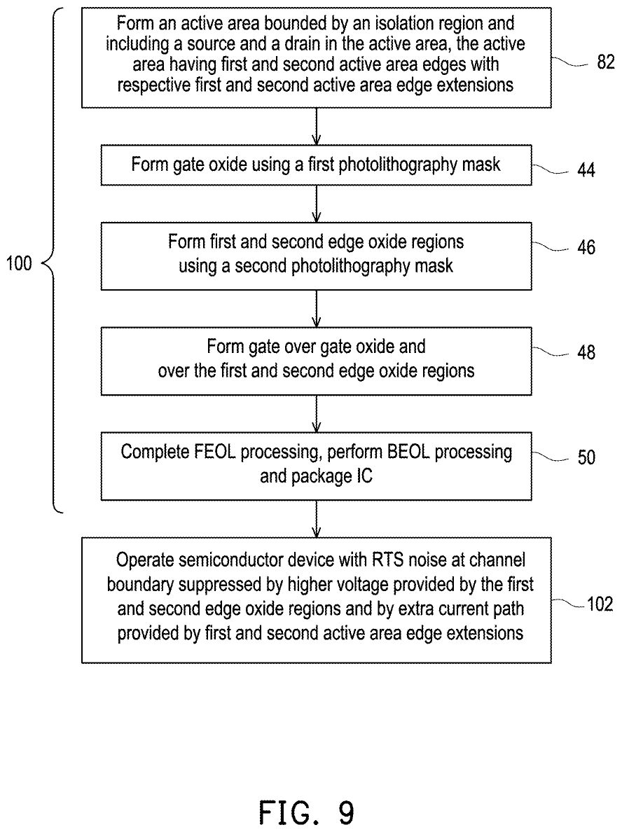

With reference to FIG. 9, further embodiments are contemplated that combine the first edge oxide region 20 and a second edge oxide region 22 disposed on edges of the gate oxide Gₒₓ as described with reference to FIGS. 1 and 2 with first and second active area edge extensions 61 and 62 that increase a width in the transverse direction d_{T} of the active area 60 at the edge extensions 61, 62 to a width Wₑₓₜ that is greater than a minimum width Wₘᵢₙ in the transverse direction d_{T} of the active area 60 as described with reference to FIGS. 5 and 6. Corresponding device fabrication embodiments such as a fabrication process 100 illustrated in FIG. 9 suitably include the operation 82 of FIG. 8 in which the active area is formed with the edge extensions 61, 62 using a suitable OD mask or the like, and followed by the operations 44, 46, 48, and 50 of FIG. 4, particularly including the operation 46 of FIG. 4 in which the edge oxide regions 20 and 22 are formed using a different mask than that used to define the gate oxide Gₒₓ. In an operation 102, the semiconductor device fabricated by the fabrication process 100 is operated. In the device operation 102, RTN is suppressed by the higher voltage at the edges of the channel compared with in the central region 28 of the channel, as previously described for the operation 52 of FIG. 4. Additionally, in the device operation 102 RTN is also suppressed by the gradually extra current path provided by the active area edge extensions 61 and 62 (or analogous active area edge extensions of the embodiments of FIGS. 7(A)-7(E)), as previously described for the operation 92 of FIG. 8.

In the following, some further embodiments are described.

In a nonlimiting illustrative embodiment, a method of manufacturing a semiconductor device is disclosed. The method includes forming an active area bounded by an isolation region and including a source and a drain in the active area. The active area has a channel direction that extends between the source and the drain and a transverse direction that is transverse to the channel direction, and the active area has first and second active area edges on opposite sides of the active area that extend along the channel direction between the source and the drain. A gate oxide is formed on a portion of the active area disposed between the source and the drain. After forming the gate oxide, first and second edge oxide regions are formed on the gate oxide with edges of the respective first and second edge oxide regions coinciding with the respective first and second active area edges. The first and second edge oxide regions do not extend over a central area of the gate oxide. After forming the first and second edge oxide regions, a gate is formed over the gate oxide and over the first and second edge oxide regions.

In a nonlimiting illustrative embodiment, a method of manufacturing a semiconductor device is disclosed. The method includes forming an active area bounded by an isolation region and including a source and a drain in the active area. The active area has a channel direction that extends between the source and the drain and a transverse direction that is transverse to the channel direction and the active area has first and second active area edges on opposite sides of the active area that extend along the channel direction between the source and the drain. A gate oxide is formed on a portion of the active area disposed between the source and the drain. A gate is formed over the gate oxide. The active area has a minimum width along the transverse direction. The first and second active area edges have respective first and second active area edge extensions that increase a width in the transverse direction of the active area at the edge extensions to a width greater than the minimum width. Furthermore, the gate does not completely cover the first and second active area edge extensions along the channel direction.

In a nonlimiting illustrative embodiment, a semiconductor device is disclosed, which comprises an active area bounded by an isolation region and including a source and a drain in the active area. The active area has a channel direction that extends between the source and the drain and a transverse direction that is transverse to the channel direction and the active area has first and second active area edges on opposite sides of the active area that extend along the channel direction between the source and the drain. A gate oxide is disposed on a portion of the active area between the source and the drain, and a gate is disposed over the gate oxide. The semiconductor device further includes a noise suppressing structure including at least one of: (i) first and second edge oxide regions disposed on the gate oxide with edges of the respective first and second edge oxide regions coinciding with the respective first and second active area edges, the first and second edge oxide regions not extending over a central area of the gate oxide and the gate disposed over the first and second edge oxide regions; and/or (ii) first and second active area edge extensions of the respective first and second active area edges that increase a width in the transverse direction of the active area at the edge extensions to a width greater than a minimum width of the active area in the transverse direction, wherein the gate does not completely cover the first and second active area edge extensions along the channel direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming an active area bounded by an isolation region and including a source and a drain in the active area, wherein the active area has a channel direction that extends between the source and the drain and a transverse direction that is transverse to the channel direction and the active area has first and second active area edges on opposite sides of the active area that extend along the channel direction between the source and the drain;
forming a gate oxide on a portion of the active area disposed between the source and the drain;
after forming the gate oxide, forming first and second edge oxide regions on the gate oxide with edges of the respective first and second edge oxide regions coinciding with the respective first and second active area edges, the first and second edge oxide regions not extending over a central area of the gate oxide; and
after forming the first and second edge oxide regions, forming a gate over the gate oxide and over the first and second edge oxide regions.

2. The method of claim 1, wherein the gate completely covers the first and second edge oxide regions.

3. The method of claim 1, wherein:
the forming of the gate oxide uses a first photolithography mask; and
the forming of the first and second edge oxide regions on the gate oxide uses a second photolithography mask different from the first photolithography mask.

4. The method of claim 1, wherein the method does not include forming ion implantation regions in the active area underneath the first and second edge oxide regions.

5. The method of claim 1, wherein the gate oxide has a thickness of 4.0 nanometers or less.

6. The method of claim 1, further comprising forming a self-aligned silicide over the gate.

7. The method of claim 1, wherein:
the first and second active area edges have respective first and second active area edge extensions that increase a width in the transverse direction of the active area at the edge extensions to a width greater than a minimum width of the active area in the transverse direction; and
the gate does not completely cover the first and second active area edge extensions along the channel direction.

8. A method of manufacturing a semiconductor device, the method comprising:
forming an active area bounded by an isolation region and including a source and a drain in the active area, wherein the active area has a channel direction that extends between the source and the drain and a transverse direction that is transverse to the channel direction and the active area has first and second active area edges on opposite sides of the active area that extend along the channel direction between the source and the drain;
forming a gate oxide on a portion of the active area disposed between the source and the drain; and
forming a gate over the gate oxide;
wherein the active area has a minimum width along the transverse direction;
wherein the first and second active area edges have respective first and second active area edge extensions that increase a width in the transverse direction of the active area at the edge extensions to a width greater than the minimum width; and
wherein the gate does not completely cover the first and second active area edge extensions along the channel direction.

9. The method of claim 8, wherein:
the first and second active area edge extensions extend beyond the gate toward the source along the channel direction; and
the first and second active area edge extensions extend beyond the gate toward the drain along the channel direction.

10. The method of claim 8, wherein the first and second active area edge extensions comprise respective first and second polygonal, rectangular, or arcuate areas that are not completely covered by the gate.

11. The method of claim 8, wherein the first and second active area edge extensions comprise respective first and second sawtooth, circle-tooth, or square-tooth areas that are not completely covered by the gate.

12. The method of claim 8, further comprising forming a self-aligned silicide over the gate.

13. The method of claim 8, wherein the gate oxide has a thickness of 4.0 nanometers or less.

14. The method of claim 8, further comprising:
after forming the gate oxide and before forming the gate, forming first and second edge oxide regions on the gate oxide with edges of the respective first and second edge oxide regions coinciding with the respective first and second active area edges, the first and second edge oxide regions not extending over a central area of the gate oxide.

15. The method of claim 14, wherein:
the forming of the gate oxide uses a first photolithography mask; and
the forming of the first and second edge oxide regions on the gate oxide uses a second photolithography mask different from the first photolithography mask.

16. A semiconductor device, comprising:
an active area bounded by an isolation region and including a source and a drain in the active area, wherein the active area has a channel direction that extends between the source and the drain and a transverse direction that is transverse to the channel direction and the active area has first and second active area edges on opposite sides of the active area that extend along the channel direction between the source and the drain;
a gate oxide disposed on a portion of the active area between the source and the drain;
a gate disposed over the gate oxide; and
a noise suppressing structure including at least one of:
(i) first and second edge oxide regions disposed on the gate oxide with edges of the respective first and second edge oxide regions coinciding with the respective first and second active area edges, the first and second edge oxide regions not extending over a central area of the gate oxide and the gate disposed over the first and second edge oxide regions; and/or
(ii) first and second active area edge extensions of the respective first and second active area edges that increase a width in the transverse direction of the active area at the edge extensions to a width greater than a minimum width of the active area in the transverse direction, wherein the gate does not completely cover the first and second active area edge extensions along the channel direction.

17. The semiconductor device of claim 16, wherein the noise suppressing structure includes said first and second edge oxide regions.

18. The semiconductor device of claim 17, wherein the gate completely covers the first and second edge oxide regions.

19. The semiconductor device of claim 16, wherein the noise suppressing structure includes said first and second active area edge extensions.

20. The semiconductor device of claim 19, wherein:
the first and second active area edge extensions extend beyond the gate toward the source along the channel direction; and
the first and second active area edge extensions extend beyond the gate toward the drain along the channel direction.
